(19) United States
(12) Patent Application Publication
(10) Pub. No.: US 2017/0289420 A1
(43) Pub. Date: Oct. 5, 2017

(54) IMAGER MODULE FOR A VEHICLE CAMERA AND METHOD FOR THE MANUFACTURE THEREOF

(71) Applicant: Robert Bosch GmbH, Stuttgart (DE)

(72) Inventors: Martin Reiche, Weil Der Stadt (DE); Thomas Braune, Calw (DE); Ulrich Seger, Leonberg-Warmbronn (DE)

(21) Appl. No.: 15/507,326

(22) PCT Filed: Jul. 31, 2015
(86) PCT No.: PCT/EP2015/067649

§ 371 Date: Feb. 28, 2017

(30) Foreign Application Priority Data
Aug. 29, 2014 (DE) 10 2014 217 295.0

(51) Int. Cl. H04N 5/225; B60R 1/00; H01L 23/00; G03B 17/55; H01L 27/146

(52) U.S. Cl. CPC H04N 5/2257; H04N 5/2254; H04N 5/2253; H04N 5/2252; G03B 17/55; H01L 27/14636; H01L 24/73; H01L 24/16; H01L 24/83; B60R 1/00; H01L 2224/73204; H01L 2224/16225; H01L 2224/83855; B60R 2300/10

(57) ABSTRACT

An imager module for a vehicle camera, the imager module having at least: a lens holder, a lens accommodated in the lens holder, a flexible conductor device having leads, and an image sensor contacted by the leads of the flexible conductor device that has a front side having a sensitive surface; the image sensor being contacted by the leads using flip-chip technology via stud bumps provided at the front side thereof. The lens holder has a plastic part, in particular an injection-molded part, having a tubular region for accommodating the lens and a fastening region having a bottom side; and the flexible conductor device being integrally attached to the bottom side of the fastening region, and a non-conductive adhesive region being formed between the front side of the image sensor and the flexible conductor device around the stud bumps, preferably to produce a tensile stress. An insertion part is preferably received in the plastic body.

### BACKGROUND INFORMATION

An imager module for a vehicle camera is generally accommodated in a camera housing, together with other electrical components and a circuit board, for example. Here, the imager module already has a lens, a lens holder that holds the lens, a carrier device for accommodating and contacting the image sensor, and the image sensor itself. In the case of flip chip imager modules, the image sensor is contacted via contact means, for example, stud bumps, provided on the top side thereof having the sensitive surface, and, by the sensitive surface thereof, it faces the lens through a recess of the carrier device.

For this purpose, the lens holder can be fastened to a rigid carrier device, such as a metal plate (stiffener), to which a flexible conductor device, what is commonly known as a flex conductor, for example, is fastened.

Lens holders fabricated using MID (molded interconnect device) technology are also known that have conductor track structures produced by passive electroplating. A flip chip method is used to mechanically mount an image sensor on the conductor track structures. It is then contacted via stud bumps. A friction welding method may be used to place the stud bumps on the image sensor.

To some extent, however, contacts for the image sensor on MID structures require complex technical implementations. In NCA flip chip methods, an electrical connection of the stud bumps to the conductor tracks of the MID surfaces is ensured by the application of a pressure force to the contact surface of the conductor track, at the end face of the stud bumps, over the service life of the product. This involves technical challenges, in particular because of the flatness of the MID plastic body, the flatness and roughness of the conductor track, and the mechanical strength of the track under high pressure, also relative to the uniformity of the pressure force in the relevant temperature range and over the service life.

A post-processing of a plastic component used on an MID basis is generally not possible after the injection process because electroplating seeds are hereby exposed over the surface. It is then not possible to produce a structured layout on the planarized surface of an MID plastic. ICA methods use conductive adhesives for contacting; however, difficulties may arise here directly because of the short-circuiting risks posed by the precision rasterization or the fine pitch of the image sensor of, for instance, 100 μm. ACA methods use conductive adhesives having a lower concentration of conductive particles, which only form electrical contacts in compressed regions; however, they require a low surface roughness and substantial flatness of the join partners.

European Patent No. 1 081 944 B1 describes a metal plate design including a flex conductor that is adhesively bonded over the entire surface, as well as an imager (image sensor) mounted on the flex conductor using flip chip technology.

### SUMMARY

The imager module according to the present invention and the method for the manufacture thereof provide a few advantages:

The image sensor is contacted using flip chip technology, i.e., via contact means provided on the upper surface thereof having the sensitive surface; the image sensor being contacted via a flexible conductor device thereof that is integrally attached to a plastic body that already constitutes the lens holder, respectively includes the important constituent parts of the lens holder. Thus, the plastic body has a tubular region for receiving the lens and a fastening region to which the flexible conductor device is integrally attached.

Here, the plastic body may, in particular, be formed as an injection-molded part, preferably with the injection direction corresponding to the subsequently configured optical axis. This is based on the realization that important functional parts of the imager module, namely a tubular region for receiving the lens and a fastening region may be formed as an injection-molded part, to which a flexible conductor device, respectively a flex conductor may be directly integrally attached. It is thus already made possible to both house the lens, as well as directly attach the image sensor by using an injection-molded part and a flexible conductor device laminated thereon having a plastic matrix or plastic film, and metallic leads accommodated in the plastic film, by applying flip chip technology via stud bumps, for example.

The present invention recognizes that it is difficult to contact the image sensor solely via stud bumps on a flexible conductor device, particularly because of the problems associated with adhesion of the stud bumps to the flexible conductor device; for that reason, an NCA (in particular, electrically non-conductive adhesive) is introduced into adhesive regions between the image sensor and the flexible conductor device, in particular around the stud bumps. An adhesive is preferably used that subsequently shrinks during curing. A tensile stress, which presses the stud bump against the flexible conductor device and thus ensures an effective contacting, is thereby produced between the image sensor and the flexible conductor device. The otherwise often disadvantageous effect of an adhesive shrinkage is thus advantageously utilized to improve contacting. Basically, any adhesives that shrink (undergo volume reduction) may be used during the curing thereof, for example, even epoxy-based adhesives.

A simple manufacturing is thus made possible that involves relatively few manufacturing steps and provides substantial process reliability. In comparison to MID designs of the lens holder that include conductor tracks to be formed by passive electroplating, a few advantages are derived, in particular:

Thus, the plastic material of the lens holder may basically be freely selected; it advantageously being producible by an injection molding process; however, such a production using an injection molding process does not constitute a relevant restriction of plastic materials. Cost advantages for the material are derived, on the one hand, and process-engineering advantages, on the other hand, in comparison with special plastic materials required for MID processes to expose metal structures by laser ablation or laser writing and allow a subsequent passive electroplating. In particular, a plastic having a high pressure resistance and/or a substantial rigidity may be selected in accordance with the present invention.

Toward the top side thereof, the flexible conductor device, respectively the flex conductor may feature the plastic material, respectively the plastic film, and toward the bottom side, at least in some regions, exposed metallic leads, for example, of rolled copper. The flexible conductor device may hereby be laminated to the bottom side of the fastening region of the plastic body, i.e., integrally attached by a localized softening. Thus, there is no need for a fastening by adhesive bonding. In terms of process engineering, a lamination is simple here and is reliably ensured. Even the metallic leads are not adversely affected by the lamination.

Here, the flexible conductor device may have one or a plurality of layers of conductors. The multilayer layout allows an unbundling of the individual conductors.

The plane and pressure-stabile counter surface for mounting the image sensor using the flip chip method is made possible, for example, by post-processing or by an insertion part to be inserted having a defined, planar bottom side.

The adhesive that shrinks during curing allows an effective contacting of the stud bumps and of the flexible conductor device over the service life thereof.

A further advantage resides in the possibility of receiving one or a plurality of insertion parts in the injection-molded body. In the first place, the insertion parts may enhance a mechanical stability; in particular, even with a planar bottom side, an insertion part may also provide a plane, pressure-resistant and suitable reference surface for the flex conductor in the region of contacting of the image sensor, so that a fixed, planar flip chip counter support is achieved here for the image sensor to be installed.

In addition, an injection-molded plastic body also makes possible a post-processing of the bottom surface thereof, without problems occurring as in the case of the specific MID molded articles that do not allow a mechanical post-processing due to the special layer structure thereof.

In addition, the insertion part also makes it possible to form an aperture having a sharp edge around the optical axis in order to sharply limit the illumination field of the image sensor's active surface.

In addition, the insertion part may be provided to allow heat to be dissipated from the image sensor. Thus, the insertion part may also be metallic, for example, and extend outwardly through the plastic part in order to be connected here, for example, to a metallic chamber housing.

### BRIEF DESCRIPTION OF THE DRAWINGS

FIG. 1 shows an imager module for a vehicle camera in accordance with a first specific embodiment in cross section through the optical axis.

FIG. 2 shows a corresponding illustration in accordance with another specific embodiment.

FIG. 3 shows a detail enlargement from FIGS. 1 and 2.

### DETAILED DESCRIPTION

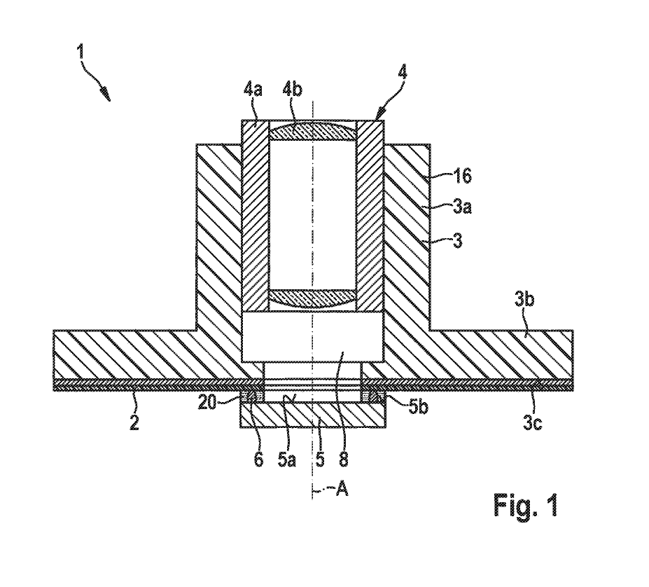

An imager module 1 is provided in particular for use in a vehicle camera and, in accordance with FIG. 1, has a carrier device 2, a lens holder 3 (lens housing), a lens 4 and an image sensor 5 (imager chip). Imager module 1 is subsequently generally housed in a camera housing along with other electrical or electronic components, for example, and, in the automotive sector, is preferably accommodated in the passenger compartment of a vehicle.

Lens 4 has a lens mount 4a and lenses 4b received therein and, for focusing, is accommodated longitudinally displaceably in the direction of an optical axis A in a tubular region 3a of lens holder 3; imager module 1 is advantageously designed as a fix-focus module having a lens 4 that is fixed in position once focusing is achieved; it being possible for the positional fixation to be accomplished by an adhesive or also a press fitting, for example. Lens holder 3 also features a fastening region 3b to whose bottom side in FIG. 1, carrier device 2 is fastened by top side 2a thereof.

Image sensor 5 is mounted and contacted by stud bumps 6 at a bottom side 2b of carrier device 2 and, by sensitive surface 5a thereof, faces lens 4 through recess 8 formed in carrier device 2, i.e., forwardly, in image-capturing direction. Thus, flip chip technology is used to mount image sensor 5 on carrier device 2.

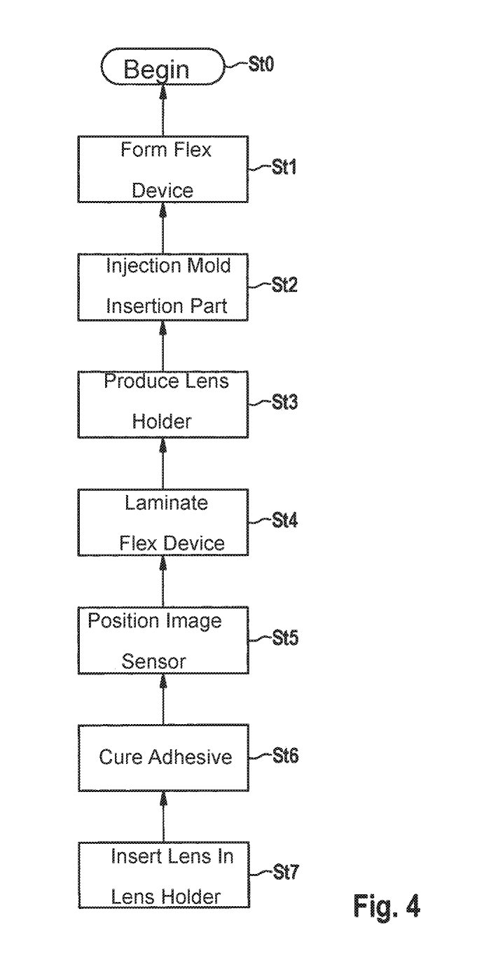

Carrier device 2 is shown in greater detail in FIG. 3, in particular, and has metallic leads 10, preferably of rolled copper, embedded in a plastic matrix 11, for example, a plastic film or thin, flexible plastic sheet. The plastic material may be polyimide, for example. Thus, carrier device 2 is designed as a flexible conductor device or flex conductor. Flexible conductor device 2 is laminated by top side 2a thereof onto fastening region 3b of lens conductor 3, i.e., integrally joined by a localized melting. Image sensor 5 is contacted by metallic leads 10 of flexible conductor device 2 via stud bumps 6.

Metallic leads 10, for example, copper leads 10, are advantageously exposed toward bottom side 2b of the flexible conductor device to allow image sensor 5 to be directly contacted here via stud bumps 6.

Formed around stud bumps 6 are adhesive regions 20, into which a non-conductive adhesive 21 (NCA) is introduced that undergoes shrinkage or volume reduction during curing. Thus, adhesive regions 20 extend from top side 5a of the image sensor to bottom side 2b of flexible conductor device 2; i.e., they adhesively bond image sensor 5 to flexible conductor device 2. A tensile stress is thereby produced that presses stud bumps 6 against bottom side 2b of flexible conductor device 2.

Plastic body 16 of the specific embodiment of FIG. 1 may, in particular, be post-processed at bottom side 3c, at least in the region around optical axis A, to form a planar reference surface here for flexible conductor device 2, to form a flip chip counter support here, respectively a, on the one hand, mechanically stable and, on the other hand, defined planar reference surface for the flip chip assembly of image sensor 5.

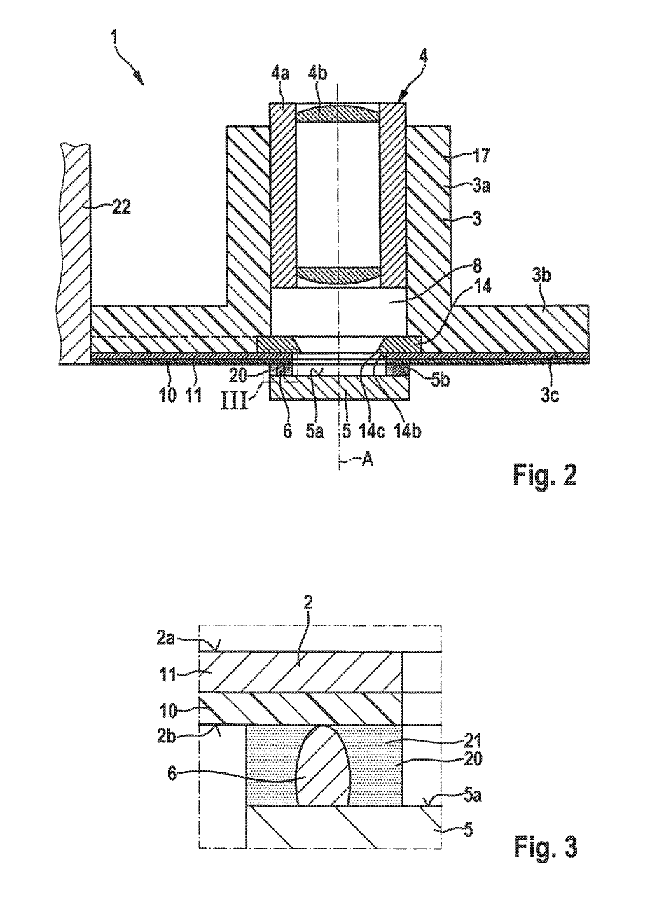

On the other hand, in the specific embodiment of FIG. 2, this planar reference surface is provided by an insertion part 14. Insertion part 14 is preferably annular and concentrically positioned relative to optical axis A. Insertion part 14 may be made of a metal, for example, or of a rigid plastic, and it enhances the rigidity of lens holder 3, particularly in the area where image sensor 5 is connected; thus, it is used as a counter support for mounting image sensor 5 using the flip chip method.

Insertion part 14 may also engage the inner free space of tubular region 3a of lens holder 3 from behind or provide a back taper therefor; thereby making possible a more variable form design.

Insertion part 14 is also used, in particular, as a fixed base support for flexible conductor device 2 in the area of mounting support thereof for image sensor 5. To this end, insertion part 14 has a defined, planar insertion-part bottom side 14b, that may be secured in position by post-processing and is used as a planar reference surface for mounted, flexible conductor device 2.

In this case, insertion part 14 makes possible further embodiments and advantages. Thus, in accordance with FIG. 2, the insertion part may be formed with a sharp edge 14c toward optical axis A; thus serves as an aperture to exactly define an illumination field of sensitive surface 5a of image sensor 5. Thus, the optical properties of image sensor 5 and of entire imager module 1 are improved.

As explained above, insertion part 14 may be placed annularly around the optical axis and thus be laterally outwardly encircled by plastic body 17. However, it is also possible to configure insertion part 14 to have a larger lateral extent, respectively larger dimensions. At the same time, insertion part 14 may also be used as a heat sink, respectively for dissipating heat from image sensor 5. To this end, in accordance with the configuration shown in dashed lines on the left in FIG. 2, for example, it is also advantageous to provide a more forward configuration of the insertion part, laterally outwardly, for the contacting of a camera housing 22 indicated in FIG. 2, making possible a direct outward heat dissipation.

Thus, the manufacturing method according to the present invention advantageously includes the following steps in accordance with FIG. 4:

Subsequently to the initiation of step St0, the flex conductor or flexible conductor device 2 is formed in step St1 by embedding metallic leads 10 in plastic matrix 11.

Lens holder 3 is produced in an injection molding process in step St3; it being alternatively possible for insertion part 14 to also be injection molded already in step St2, i.e., inserted in an injection tool and injection molded by the plastic material of lens holder 3; insertion part 14 may alternatively be subsequently inserted into injection-molded plastic body, as shown by a dashed line in FIG. 2 and preferably be adhesively bonded in place. In both alternatives, insertion part 14 is integrally accommodated in plastic body of lens holder 3 and fastened in place.

Flexible conductor device 2 is subsequently laminated to bottom side 3c of fastening region 3b in step St4, i.e., preferably softened by localized melting and hereby bonded or form-fittingly joined.

Image sensor 5 is subsequently positioned on bottom side 2b of flex conductor 2 using flip chip technology in step St5 and contacted by metallic leads 10 using stud bumps 6; adhesive 21 being introduced into adhesive regions 20.

Adhesive 21 subsequently cures in step St6, for example, thermally or by UV radiation, or also as cold curing adhesive following the curing time thereof, producing the tensile stress.

In step St7, lens 4 may subsequently be inserted in a generally known manner from the front (thus, from above in the figures) into tubular region 3a of lens holder 3 in axial direction A, and a focus position may be found by a focusing, for example, by recording a test pattern and evaluating the image signals from image sensor 5; and, for this, lens 4 may be fixed in position in tubular region 3a, whereby imager module 1 is completed.

1.-14. (canceled)

15. An imager module for a vehicle camera, the imager module comprising:
a lens holder;
a lens accommodated in the lens holder;
a flexible conductor device having leads; and
an image sensor contacted by the leads of the flexible conductor device and having a front side that includes a sensitive surface, wherein:
the image sensor is contacted by the leads in a flip-chip technique via stud bumps provided at the front side of the image sensor,
the lens holder has a plastic body that includes a tubular region for accommodating the lens and a fastening region having a bottom side,
the flexible conductor device is integrally attached to the bottom side of the fastening region, and
a non-conductive adhesive region is formed between the front side of the image sensor and the flexible conductor device.

16. The imager module as recited in claim 15, wherein:
the leads include metallic leads, and
the flexible conductor device includes a plastic matrix via which the flexible conductor device is welded to the bottom side of the fastening region.

17. The imager module as recited in claim 16, wherein the plastic matrix is welded to the bottom side of the fastening region by one of lamination and local softening.

18. The imager module as recited in claim 15, wherein:
the leads include metallic leads,
the flexible conductor device includes a plastic matrix in which the metallic leads are disposed, and
the metallic leads are exposed to a bottom side of the flexible conductor device.

19. The imager module as recited in claim 15, wherein the stud bumps are configured in the adhesive region.

20. The imager module as recited in claim 15, wherein a tensile stress, which presses the stud bumps against the leads of the flexible conductor device, is produced by the adhesive region between the front side of the image sensor and the flexible conductor device.

21. The imager module as recited in claim 15, wherein:
the plastic body is formed as an injection-molded part, and
the tubular region and the fastening region are regions of the injection-molded part.

22. The imager module as recited in claim 15, further comprising:
at least one insertion part integrally accommodated in the plastic body, and
the insertion part reinforces the flexible conductor device in a region of contact means for contacting the image sensor.

23. The imager module as recited in claim 22, wherein, in the flexible conductor device, a recess is formed through which the sensitive surface of the image sensor faces the lens, the insertion part being provided one of in a region of the recess and around the recess.

24. The imager module as recited in claim 22, wherein the insertion part is injection-molded into the injection-molded part.

25. The imager module as recited in claim 22, wherein the insertion part has an edge radially facing an optical axis for forming an aperture for the sensitive surface of the image sensor.

26. The imager module as recited in claim 22, wherein the insertion part is metallic and extends in the plastic body radially outwardly through the fastening region for connection to a camera housing for dissipating heat from the image sensor.

27. A method for manufacturing an imager module for a vehicle camera, comprising:
producing a flexible conductor device having a plastic matrix and metallic leads;
forming a plastic body of a lens holder using an injection molding process, the plastic body having a tubular region and a fastening region having a bottom side;
one of welding and laminating the flexible conductor device to the bottom side of the fastening region;
mounting and contacting an image sensor using a flip-chip technology via stud bumps on a bottom side of the flexible conductor device while thereby contacting the metallic leads of the flexible conductor device and introducing a non-conductive adhesive between the bottom side of the flexible conductor device and the image sensor;
curing the non-conductive adhesive, with shrinkage taking place and a tensile stress being produced between the bottom side of the flexible conductor device and the image sensor; and
inserting a lens into the tubular region of the lens holder.

28. The method as recited in claim 27, further comprising:
injection-molding into the plastic body an insertion part having a planar insertion-part bottom side, wherein the flexible conductor device includes has a recess around an optical axis;
securing the flexible conductor device to an edge of the recess at the bottom side of the insertion part.
